(19) United States
(12) Patent Application Publication
(10) Pub. No.: US 2025/0125583 A1
(43) Pub. Date: Apr. 17, 2025

(54) LASER DEVICE

(71) Applicant: TRUMPF Photonic Components GmbH, Ulm (DE)

(72) Inventors: Stephan Gronenborn, Aachen (DE); Simeon Renz, Illerkirchberg (DE); Roman Koerner, Lonsee (DE)

(21) Appl. No.: 18/988,968

(22) Filed: Dec. 20, 2024

Related U.S. Application Data
(63) Continuation of application No. PCT/EP2023/067185, filed on Jun. 23, 2023.

(30) Foreign Application Priority Data
Jun. 27, 2022 (DE) 10 2022 115 935.3

(51) Int. Cl. H01S 5/068; H01S 5/028; H01S 5/183

(52) U.S. Cl. CPC H01S 5/06821; H01S 5/0287; H01S 5/18361

(57) ABSTRACT

A vertical cavity surface emitting laser (VCSEL) includes a main body having a resonator for forming a particular laser mode. The resonator has an inner Bragg mirror and a coupling-out mirror which is adjacent to an outer face of the main body, and an active layer arranged between the inner Bragg mirror and the coupling-out mirror for generating light. On the outer face, an emission region is provided that has at least two coupling-out facets positioned at locations on the outer face that match locations of intensity maxima of the particular laser mode such that the particular laser mode is stabilized. The at least two coupling-out facets have a facet reflectivity that is higher than a surface reflectivity of a remaining of the emission region. The at least two coupling-out facets have a non-circular outer contour.

### CROSS REFERENCE TO RELATED APPLICATIONS

This application is a continuation of International Application No. PCT/EP2023/067185 (WO 2024/002906 A1), filed on Jun. 23, 2023, and claims benefit to German Patent Application No. DE 10 2022 115 935.3, filed on Jun. 27, 2022. The aforementioned applications are hereby incorporated by reference herein

### FIELD

Embodiments of the present invention relate to a vertical cavity surface emitting laser (VCSEL) for emitting laser light.

### SUMMARY

Embodiments of the present invention provide a vertical cavity surface emitting laser (VCSEL). The VCSEL includes a main body having a resonator for forming a particular laser mode. The resonator has an inner Bragg mirror and a coupling-out mirror which is adjacent to an outer face of the main body, and an active layer arranged between the inner Bragg mirror and the coupling-out mirror for generating light. On the outer face, an emission region is provided that has at least two coupling-out facets positioned at locations on the outer face that match locations of intensity maxima of the particular laser mode such that the particular laser mode is stabilized. The at least two coupling-out facets have a facet reflectivity that is higher than a surface reflectivity of a remaining of the emission region. The at least two coupling-out facets have a non-circular outer contour.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIGS. 1, 2, and 4 to 7 show different exemplary embodiments of facet rows;

FIG. 3 shows a graph with an exemplary laser mode according to some embodiments; and

FIG. 8 shows a coupling-out facet surrounded by a lowering region according to some embodiments.

### DETAILED DESCRIPTION

Embodiments of the present invention provide a VCSEL having a main body, which has a resonator for forming a particular laser mode, and which has an inner Bragg mirror and a Bragg mirror which is adjacent to an outer face of the main body which functions as a coupling-out mirror, wherein an active layer for generating light is arranged between the Bragg mirrors, wherein on the outer face an emission region is provided that has at least two coupling-out facets which are positioned at locations on the outer face that match locations of intensity maxima of the laser mode such that the particular laser mode is stabilized, wherein the coupling-out facets have a facet reflectivity that is higher than a surface reflectivity of the remaining emission region, wherein the coupling-out facets do not have a circular outer contour.

The emission region is formed on the outer face of the coupling-out mirror, while the coupling-out facets are enclosed by the emission region. The respective coupling-out facets are positioned at locations where the intensity maxima of a specific laser mode are formed. This promotes and stabilizes this particular laser mode, since the light at the locations of the intensity maxima is reflected into the cavity between the Bragg mirrors, while the light in the area of the remaining emission region is reflected less in comparison.

Further embodiments and developments are listed in the dependent claims.

Advantageously, the outer contour has a greater extension along a length axis than along a width axis, wherein the length axis is aligned perpendicular to the width axis, wherein the length axis and the width axis are aligned parallel to the outer face. The length axis and the width axis are aligned perpendicular to a stacking direction of the Bragg mirrors. Preferably, the width axis is arranged along the greatest width and the length axis is arranged along the greatest length of the outer contour.

Preferably, the outer contour is substantially elliptical, rectangular or diamond-shaped. For example, the width axis is the semi-minor axis and the length axis is the semi-major axis of the ellipse. The same applies to the diagonals of the diamond shape or the side lengths of the rectangle, so that the dimension of the width axis is smaller than the dimension of the length axis.

In a particular development, at least two outer contours are shaped differently compared to one another. At least two coupling-out facets have outer contours that do not have an identical shape. This can promote certain modes.

It is preferred to arrange a facet row with more than two coupling-out facets along an imaginary line, wherein the outermost coupling-out facet at the respective longitudinal ends of the facet row has an outer contour which is preferably different from the other coupling-out facets of the facet row.

Advantageously, at least two contour distances along the imaginary line between two directly adjacent outer contours are of different sizes, wherein the contour distance is positioned between directly adjacent intersection points of the respective outer contour with the imaginary line. The contour distances are the distances between the next contour sections of two adjacent outer contours.

It is preferred that the distances between central outer contours with respect to the imaginary line are smaller than the remaining distances between adjacent outer contours of the same facet row.

In order to achieve efficient light extraction, two directly adjacent outer contours can intersect so that they merge into one another.

In order to achieve polarization of the coupled-out light, a polarization grating can be arranged on at least one coupling-out facet, wherein preferably at least two central coupling-out facets of the facet row have a polarization grating.

An advantageous further development can include that the facet reflectivity of the coupling-out facets in the region of the outer contour continuously decreases along a lowering section to the level of the surface reflectivity of the remaining emission region, wherein the lowering section has a shortest dimension along which the facet reflectivity decreases, which is preferably 0.1 to 3 micrometers. The lowering section can, for example, be designed as a seam-like circumferential area around a coupling-out facet. The lowering section can reduce diffraction effects at the edge of the coupling-out facet.

For example, the length axis can be aligned perpendicular to the imaginary line, while the width axis can be aligned parallel to or on the imaginary line.

Preferably, an intersection distance is formed between adjacent intersection points of the length axes and the imaginary line, wherein at least two intersection distances are different. Purely as an example, the intersection distances of the central coupling-out facets of the facet row are smaller than the intersection distances in the region of the longitudinal ends of the facet row. This enables optimal adjustment of the coupling-out facets according to the laser modes.

Advantageously, the intersection distance of two adjacent coupling-out facets can be smaller than the extension of one of the adjacent coupling-out facets along the width axis. As a result, the adjacent coupling-out facets overlap and the outer contours of adjacent coupling-out facets form intersection points.

It is preferred if the outer contour of at least one coupling-out facet has a straight contour section. Corners and round sections can also be provided.

Exemplary embodiments are described below with reference to the associated drawings. Direction indications in the following explanation are to be understood according to the reading direction of the drawings.

The figures show VCSELs 10 (vertical-cavity surface-emitting lasers) which have a main body 12. The main body 12 comprises a resonator 14 which is formed by two Bragg mirrors, wherein an inner Bragg mirror and a coupling-out mirror are provided as Bragg mirrors. The coupling-out mirror borders on an outer face 16 of the main body 12. Within the resonator 14, a specific laser mode 18 is formed, which is fed by light from an active layer arranged between the Bragg mirrors.

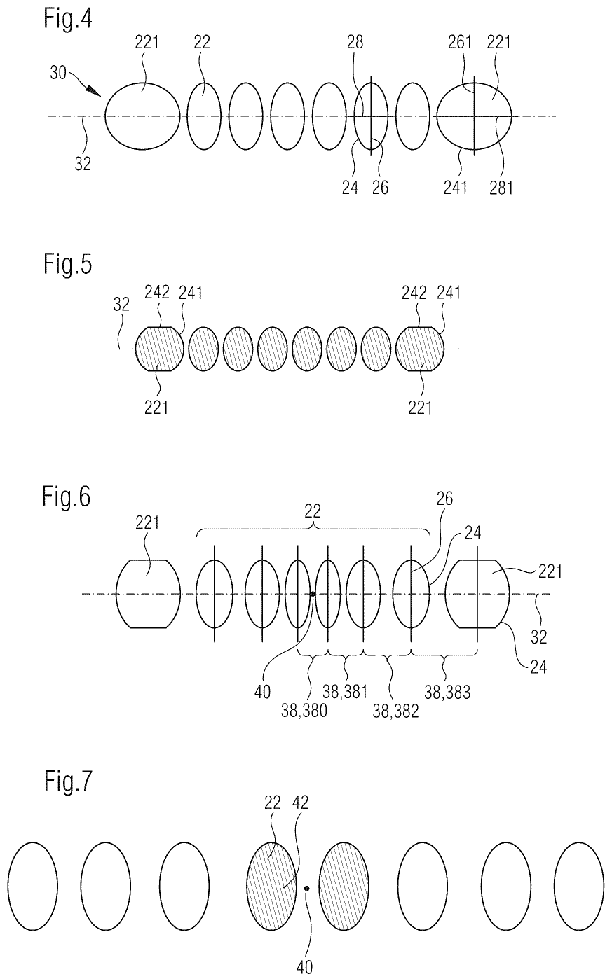

FIG. 3 shows such a laser mode 18 in which a plurality of intensity maxima 19 are arranged along an imaginary line 32. The imaginary line 32 represents the x-axis 33 and a length axis 26 represents the y-axis of the graph in FIG. 3. The curves in the graph show the intensity distribution along the axes 33, 35.

The Bragg mirrors and the active layer are stacked on top of one another, wherein a stacking direction is oriented perpendicular to the main extension planes of the layers of the Bragg mirrors and the active layer.

On the outer face 16, an emission region 20 is provided which has at least two coupling-out facets 22. The light of the laser mode 18 emerges from the coupling-out facets 22. The coupling-out facets 22 are positioned at locations on the outer face 16 which coincide with locations of intensity maxima 19 of the laser mode 18. The coupling-out facets 22 are arranged at locations on the outer face 16 which border on the spatial volumes within the resonator 14 which have the antinodes of a standing wave underlying the laser mode 18. The respective intensity maxima of the exemplary representation in FIG. 3 are also positioned in these spatial volumes.

The coupling-out facets 22 have a facet reflectivity that is higher than a surface reflectivity of the remaining emission region 20. This results in the specific laser mode 18 being stabilized since the corresponding intensity maxima are promoted.

The coupling-out facets 22 do not have a circular outer contour 24. The coupling-out facet 22 is separated from the remaining emission region 20 by the outer contour 24. The outer contour 24 separates the area with a high facet reflectivity and a low surface reflectivity.

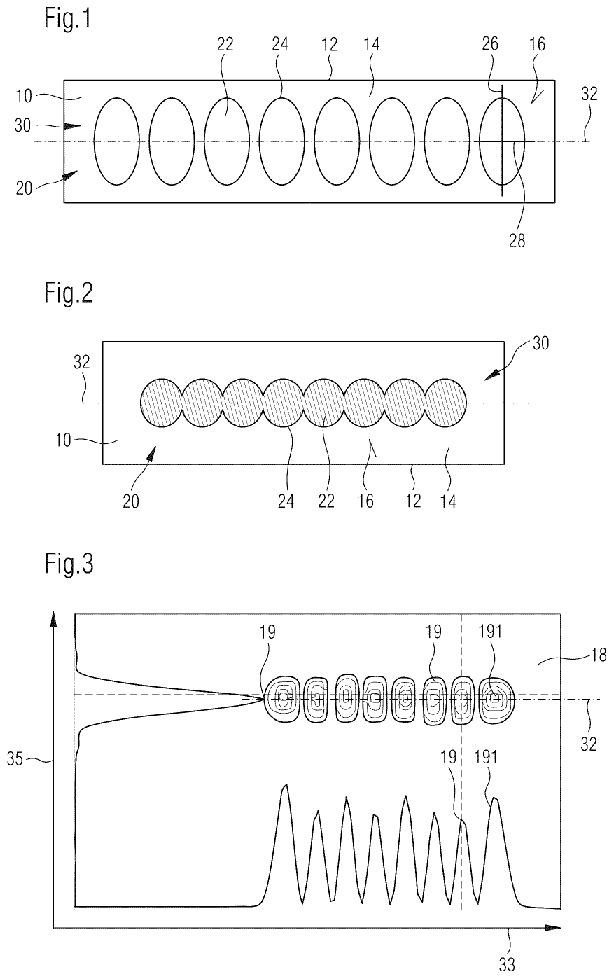

In FIG. 1, the outer contour 24 has a greater extension along a length axis 26 of the respective coupling-out facet 22 than along a width axis 28 of the coupling-out facet 22. The length axis 26 is aligned perpendicular to the width axis 28 and is aligned parallel to the outer face 16 and perpendicular to the stacking direction.

Preferably, the width axis 28 is arranged along the greatest width and the length axis 26 is arranged along the greatest length of the outer contour 24. This results in an elliptical outer contour 24. Other shapes such as rectangles or diamonds are also conceivable.

FIG. 3 shows that around the intensity maxima 19 there is an intensity distribution that is not circular. The coupling-out facets 22 and the outer contour 24 are selected accordingly.

The coupling-out facets 22 of FIG. 1 are arranged in a facet row 30 with more than two coupling-out facets 22 along an imaginary line 32. The imaginary line 32 is a straight line. The width axes 28 lie on the imaginary line 32. The imaginary line runs in particular along a common axis of symmetry of the coupling-out facets 22.

Eight coupling-out facets 22 are provided in FIG. 1 by way of example, since the laser mode 18 from FIG. 3 has eight intensity maxima 19.

FIG. 2 shows that directly adjacent outer contours 24 intersect so that they merge into one another. As a result, the coupling-out facets 22 overlap one another. The overlapping areas of the coupling-out facets 22 lie on the imaginary line 32. Accordingly, the coupling-out facets 22 are connected to one another to form a continuous facet row 30.

In FIG. 4, the respective outer contour 24 of the outermost coupling-out facets 221 at the longitudinal ends of the facet row 30 is shaped differently than the outer contours 24 of the coupling-out facets 22 between the outermost coupling-out facets 221. For example, the dimensions of the width axes 281 can be longer than the length axes 261 of the outer contour 241 of the outermost coupling-out facets 221, while the dimensions of the width axes 28 are shorter than the length axes 26 of the outer contour 24 of the remaining coupling-out facets 22.

According to FIG. 3, the laser mode 18 has intensity distributions at the outermost intensity maxima 19, which are different from the remaining intensity distribution of the respective intensity maxima 19 lying between the outermost intensity maxima 191.

Preferably, the dimensions of the coupling-out facets 22 of the facet row 30 along the respective longitudinal axes 26, 261 are the same size. In particular, only the dimensions along the width axes 28, 281 of the coupling-out facets 22, 221 are different. Preferably, the shapes of the outer contours 24 between the outermost outer contours 241 are identical to one another.

FIG. 5 shows a further embodiment in which the outermost outer contours 241 do not have an elliptical shape, as is the case with the outermost outer contours 241 in FIG. 4, but have straight contour sections 242 aligned parallel to the imaginary line 32.

FIG. 6 shows a further embodiment in which distances 38 between the length axes 26 of adjacent coupling-out facets 22 are of different sizes. In particular, the distances 38 can become smaller towards the center 40, so that the distance 380 between the two longitudinal axes 26 of the central coupling-out facets 22 is smaller than the distances 381, 382, 383 of the remaining coupling-out facets 22. The distance 38 can increase gradually starting from the center, so that the outermost distance 383 is the largest.

The distances between the outer contours 22, i.e. the contour distances, can also vary. For example, the contour distances can be measured along the imaginary line 32 between two opposite closest points of adjacent outer contours 24. The next points can also be intersection points of the outer contour 22 with the imaginary line 32. Like the distances 38, the contour distances can become larger and larger from the center outwards.

If the intersection distance of two adjacent coupling-out facets 22 is smaller than the extension of one of the adjacent coupling-out facets 22 along the width axis 28, then the coupling-out facets 22 overlap and the outer contours 24 of adjacent coupling-out facets 22 in turn form intersection points with one another. The adjacent outer contours 24 then merge into one another as shown in FIG. 3.

FIG. 7 shows a further embodiment in which the two central coupling-out facets 22 have a polarization grating 42. Alternatively, more than two coupling-out facets 22 may have a polarization grating 42. Further alternatively, only the outer coupling-out facets 22 can have a polarization grating 42 or other decentrally arranged coupling-out facets 22.

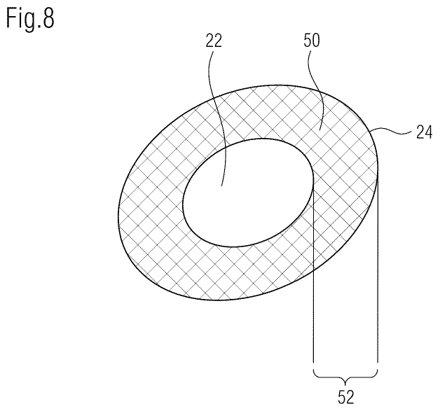

FIG. 8 shows a coupling-out facet 22 which has a lowering section 50 which is arranged in the region of the outer contour 24.

Along the lowering section 50, the facet reflectivity continuously decreases to the level of the surface reflectivity of the remaining emission region 20.

In the exemplary embodiment of FIG. 8, the reflectivity decreases along a shortest dimension 52. The dimension 52 of the lowering section 50 is preferably 0.1 to 3 micrometers.

The lowering section 50 is formed in a seam-like manner around a coupling-out facet 22 and extends along the outer contour 24. The dimension 52 can always be constant and preferably perpendicular to the outer contour 24.

The features of the embodiments can be combined with one another. Thus, the polarization grating can be used on any of the embodiments. Furthermore, the distances between the coupling-out facets can be varied in each embodiment. Likewise, the shapes of the individual coupling-out facets can be varied accordingly. It is also possible to create a plurality of facet rows, which are arranged parallel or transverse to one another, for example.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A vertical cavity surface emitting laser (VCSEL), comprising:
a main body having a resonator for forming a particular laser mode, the resonator having an inner Bragg mirror and a coupling-out mirror which is adjacent to an outer face of the main body, and an active layer arranged between the inner Bragg mirror and the coupling-out mirror for generating light, wherein, on the outer face, an emission region is provided that has at least two coupling-out facets positioned at locations on the outer face that match locations of intensity maxima of the particular laser mode such that the particular laser mode is stabilized, wherein the at least two coupling-out facets have a facet reflectivity that is higher than a surface reflectivity of a remaining of the emission region, and wherein the at least two coupling-out facets have a non-circular outer contour.

2. The VCSEL according to claim 1, wherein the outer contour has a greater extension along a length axis than along a width axis, wherein the length axis is aligned perpendicular to the width axis, and wherein the length axis and the width axis are aligned parallel to the outer face.

3. The VCSEL according to claim 1, wherein the outer contour is substantially elliptical, rectangular, or diamond-shaped.

4. The VCSEL according to claim 1, wherein at least two outer contours of the at least two coupling-out facets are shaped differently compared to one another.

5. The VCSEL according to claim 1, wherein a facet row with more than two coupling-out facets is arranged along an imaginary line, wherein an outermost coupling-out facet at a respective longitudinal end of the facet row has a respective outer contour that is different from remaining coupling-out facets of the facet row.

6. The VCSEL according to claim 5, wherein at least two contour distances along the imaginary line between two directly adjacent outer contours are different from each other, wherein each respective contour distance is positioned between directly adjacent intersection points of the respective outer contour with the imaginary line.

7. The VCSEL according to claim 6, wherein the contour distances between central outer contours with respect to the imaginary line are smaller than the contour distances between remaining adjacent outer contours of the facet row.

8. The VCSEL according to claim 1, wherein two directly adjacent outer contours intersect each other so as to merge into one another.

9. The VCSEL according to claim 1, wherein a polarization grating is arranged on at least one coupling-out facet.

10. The VCSEL according to claim 1, wherein a polarization grating is arranged on each of at least two central coupling-out facets.

11. The VCSEL according to claim 1, wherein the facet reflectivity of the coupling-out facets in a region of the outer contour continuously decreases along a lowering section to a level of the surface reflectivity of the remaining of the emission region, wherein the lowering section has a shortest dimension along which the facet reflectivity decreases.

12. The VCSEL according to claim 11, wherein the shortest dimension is in a range from 0.1 to 3 micrometers.

13. The VCSEL according to claim 5, wherein the length axis is perpendicular to the imaginary line, and the width axis is parallel to or on the imaginary line.

14. The VCSEL according to claim 13, wherein an intersection distance is formed between adjacent intersection points of the length axes and the imaginary line, wherein at least two intersection distances are different.

15. The VCSEL according to claim 14, wherein the intersection distances of the central coupling-out facets of the facet row are smaller than the intersection distances in a region of longitudinal ends of the facet row.

16. The VCSEL according to claim 15, wherein the intersection distance of two adjacent coupling-out facets is smaller than an extension of one of the adjacent coupling-out facets along the width axis.

17. The VCSEL according to claim 1, wherein the outer contour of at least one coupling-out facet has a straight contour section.
